(19) United States
(12) Patent Application Publication
(10) Pub. No.: US 2012/0180349 A1
(43) Pub. Date: Jul. 19, 2012

(54) Electrical System Devices, Indicia-Bearing Bodies, and Kits Including Same

(76) Inventor: William James Ekins, North Vancouver (CA)

(21) Appl. No.: 13/497,772

(22) PCT Filed: Sep. 23, 2010
(86) PCT No.: PCT/CA10/01525

§ 371 Date: Mar. 22, 2012

(30) Foreign Application Priority Data
Sep. 23, 2009 (CA) 2,678,609

(51) Int. Cl. G09F 13/04; H05K 7/02

(52) U.S. Cl. 40/553; 361/807

(57) ABSTRACT

An illustrative electrical system device includes a mountable electrical system device body defining a retaining region between first and second retaining surfaces for retaining an indicia-bearing body. The retaining region extends to at least one of first and second opposite sides of the electrical system device body to receive the indicia-bearing body from the at least one of the first and second opposite sides, indicia-bearing bodies, and a kit including an electrical system device and an indicia-bearing body, are also disclosed.

### RELATED APPLICATION

This application claims priority to Canadian Patent Application No. 2,678,609 filed on Sep. 23, 2009, which is incorporated by reference herein in its entirety.

### BACKGROUND

1. Field

The invention relates generally to electrical system devices, and more particularly to indicia-bearing bodies, electrical system devices configured to retain such indicia-bearing bodies, and kits including the same.

2. Related Art

In some circumstances, it may be desirable to associate information with a particular electrical system device, such as an electrical switch or receptacle, for example. Such information may include, for example, an identifier of a circuit associated with the electrical system device, information regarding proper use or function of the electrical system device, or other information relating to safe and effective use of the electrical system device.

One known electrical system device faceplate has label cover mounting recesses each having a pair of mounting slots adapted to receive and mount a label cover that is adapted to seat within the mounting recess and to be slidably insertable into and removable from the mounting slots. However, such a switch cover plate assembly disadvantageously requires inserting and removing the label covers into and from the mounting slots, which may be time-consuming and difficult. If a plurality of such faceplates cover respective such electrical system devices mounted to a wall, and are later removed when the wall is painted, for example, then the faceplates may subsequently be replaced on different such electrical system devices, in which case information on labels under the label covers of the faceplates may become associated with the wrong electrical system devices. Associating such information with a wrong electrical system device may disadvantageously lead to misuse of the electrical system device, or may disadvantageously cause misidentification of a circuit associated with the electrical system device, for example.

Alternatively, adhesives may be used to affix a label to an electrical system device. However, in some circumstances, such adhesives may fail, which may disadvantageously lead to loss of information associated with the electrical system device. Further, such adhesives may be difficult to remove, and therefore changing or removing information associated with the electrical system device may disadvantageously be time-consuming and challenging, and inability to remove adhesives may disadvantageously result in unsightly remains of unwanted labels, for example.

### SUMMARY

In accordance with one illustrative embodiment, there is provided an electrical system device having an electrical connector for connecting the electrical system device to one or more electrical wires of an electrical system. The electrical system device includes a mountable electrical system device body having first and second opposite sides and a front side between the first and second opposite sides. The electrical system device body defines: a first retaining surface on the front side; a second retaining surface on the front side and opposite at least a first portion of the first retaining surface; and a retaining region between the first and second retaining surfaces for retaining an indicia-bearing body, the retaining region extending to at least one of the first and second opposite sides to receive the indicia-bearing body from the at least one of the first and second opposite sides.

The electrical system device body may include a first translucent wall having the first retaining surface. The electrical system device body may further include an illuminant for illuminating the indicia-bearing body through the first translucent wall when the indicia-bearing body is in the retaining region.

The electrical system device body may further include a second translucent wall having the second retaining surface to permit visible indicia on the indicia-bearing body to be visible on the front side of the electrical system device body when the indicia-bearing body is in the retaining region.

The electrical system device body may include a stationary wall on the front side, the stationary wall having the first retaining surface and holding the second translucent wall.

The electrical system device body may include a movable portion on the front side, the movable portion having the first retaining surface and holding the second translucent wall.

The electrical system device body may further define a third retaining surface on the front side and opposite a second portion of the first retaining surface for retaining the indicia-bearing body in the retaining region, the third retaining surface spaced apart from the second retaining surface to expose indicia on the indicia-bearing body between the second and third retaining surfaces when the indicia-bearing body is in the retaining region.

The second and third retaining surfaces may extend at respective acute angles from the first retaining surface.

The second and third retaining surfaces may be spaced apart from the first retaining surface.

The second and third retaining surfaces may be adjacent the first retaining surface.

The second retaining surface and a surface joining the first and second retaining surfaces may be continuously curved, and the third retaining surface and a surface joining the first and third retaining surfaces may be continuously curved.

The electrical system device body may includes a stationary wall on the front side, the stationary wall having the first, second, and third retaining surfaces.

The electrical system device body includes a movable portion on the front side, the movable portion having the first, second, and third retaining surfaces.

In accordance with another illustrative embodiment, there is provided an electrical system device kit including the electrical system device and the indicia-bearing body. The indicia-bearing body defines fourth and fifth retaining surfaces complementary to the second and third retaining surfaces respectively to retain the indicia-bearing body in the retaining region of the electrical system device body.

The fourth and fifth retaining surfaces may be positioned to cause the first, second, and third retaining surfaces to retain the indicia-bearing body in the retaining region in a friction fit.

The indicia-bearing body further may have a first indicia-bearing surface between the fourth and fifth retaining surfaces.

The indicia-bearing body may further have: sixth and seventh retaining surfaces opposite the fourth and fifth retaining surfaces respectively and complementary to the second and third retaining surfaces respectively to retain the indicia-bearing body in the retaining region of the electrical system device body; and a second indicia-bearing surface between the sixth and seventh retaining surfaces and opposite the first indicia-bearing surface.

The indicia-bearing body may further define eighth and ninth retaining surfaces complementary to the second and third retaining surfaces respectively. The eighth and ninth retaining surfaces may extend perpendicularly to the third and fourth retaining surfaces. The fourth, fifth, eighth, and ninth retaining surfaces may have a common length and surround the first indicia-bearing surface.

The indicia-bearing body may define a repository for holding at least one indicia-bearing element.

The indicia-bearing body may include first and second detachably couplable portions defining the repository for holding the indicia-bearing element between the first and second detachably couplable portions when the first and second detachably couplable portions are coupled.

The first detachably couplable portion may have the fourth and fifth retaining surfaces and may define a receptacle for receiving the second detachably couplable portion.

The indicia-bearing body may include first and second latches having the fourth and fifth retaining surfaces respectively, the first and second latches being resiliently movable to permit the indicia-bearing body to move between the second and third retaining surfaces when the indicia-bearing body is urged into the retaining region towards the first retaining surface.

At least a portion of the indicia-bearing body may be translucent.

The kit may further include an indicia-bearing body holder for holding a plurality of said indicia-bearing bodies.

Other aspects and features will become apparent to those ordinarily skilled in the art upon review of the following description of specific embodiments in conjunction with the accompanying figures.

### BRIEF DESCRIPTION OF THE DRAWINGS

In drawings that illustrate various embodiments:

FIG. 1 is an oblique view of an illustrative electrical system device composite;

FIG. 2 is a side view of an electrical system device body of the electrical system device composite of FIG. 1;

FIG. 3 is a side view of an indicia-bearing body of the electrical system device composite of FIG. 1;

FIG. 4 is a side view of the electrical system device composite of FIG. 1;

FIG. 5 is a front view of another illustrative indicia-bearing body;

FIG. 6 is a front view of another illustrative indicia-bearing body;

FIG. 7 is a side view of another illustrative indicia-bearing body;

FIG. 8 is a front view of the indicia-bearing body of FIG. 7;

FIG. 9 is a rear view of the indicia-bearing body of FIG. 7;

FIG. 10 is a front view of another illustrative electrical system device composite including the electrical system device body of FIG. 2 and the indicia-bearing body of FIG. 7;

FIG. 11 is a front view of another illustrative electrical system device composite including the electrical system device body of FIG. 2 and the indicia-bearing body of FIG. 7;

FIG. 12 is an exploded side view of another illustrative indicia-bearing body;

FIG. 13 is a cross-sectional assembled view of the indicia-bearing body of FIG. 12;

FIG. 14 is an oblique view of another illustrative indicia-bearing body;

FIG. 15 is a side view of the indicia-bearing body of FIG. 14;

FIG. 16 is a side view of another illustrative electrical system device composite including the electrical system device body of FIG. 2 and the indicia-bearing body of FIG. 14;

FIG. 17 is an assembled side view of the electrical system device composite of FIG. 16;

FIG. 18 is an oblique view of another illustrative electrical system device body;

FIG. 19 is an oblique view of another illustrative electrical system device body;

FIG. 20 is an oblique view of another illustrative electrical system device body;

FIG. 21 is an oblique view of another illustrative electrical system device body;

FIG. 22 is a side view of another illustrative electrical system device body;

FIG. 23 is a side view of another illustrative electrical system device body;

FIG. 24 is an oblique view of another illustrative electrical system device body;

FIG. 25 is an oblique view of another illustrative electrical system device body;

FIG. 26 is an oblique view of another illustrative electrical system device body;

FIG. 27 is an oblique view of another illustrative electrical system device body;

FIG. 28 is an oblique view of another illustrative electrical system device body;

FIG. 29 is an oblique view of another illustrative electrical system device body;

FIG. 30 is a side view of another illustrative electrical system device body;

FIG. 31 is a side view of another illustrative electrical system device body;

FIG. 32 is side view of an illustrative indicia-bearing body holder;

FIG. 33 is an is an oblique view of the indicia-bearing body holder of FIG. 32;

FIG. 34 is a side view of another illustrative indicia-bearing body holder; and

FIG. 35 is an oblique view of the indicia-bearing body holder of FIG. 34.

### DETAILED DESCRIPTION

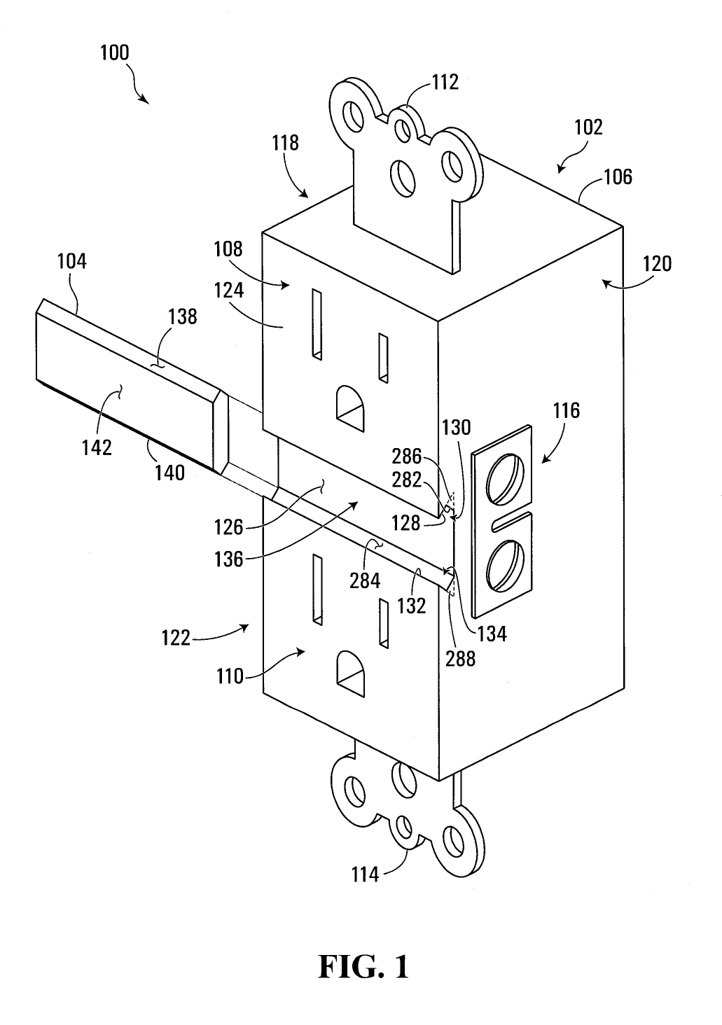

Referring to FIG. 1, an illustrative electrical system device composite is shown generally at 100 and includes an electrical system device shown generally at 102 and an indicia-bearing body 104. In the embodiment shown, the electrical system device 102 includes an electrical system device body 106 having first and second electrical receptacles shown generally at 108 and 110 for receiving and electrically coupling with an electrical plug (not shown). The electrical system device body 106 also has first and second mounting members 112 and 114 for receiving respective fasteners (not shown) to mount the electrical system device body 106 to an electrical system device box mounted to a wall (not shown), and the electrical system device body 106 is thus wall-mountable, although it will be appreciated that the electrical system device body 106 may be mounted on structures other than walls. The electrical system device body 106 also includes an electrical connector shown generally at 116 and electrically connected to the first and second electrical receptacles 108 and 110 to connect the first and second electrical receptacles 108 and 110 to one or more electrical wires of the electrical system (not shown).

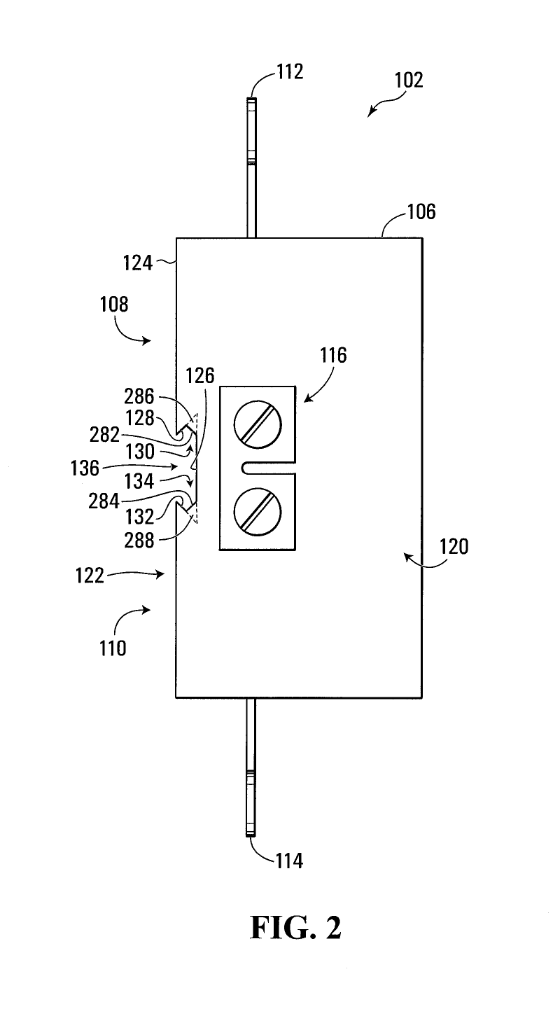

Referring to FIGS. 1 and 2, the electrical system device body 106 has first and second opposite sides shown generally at 118 and 120, and a front side shown generally at 122. The first and second electrical receptacles 108 and 110 are on the front side 122, and therefore when the electrical system device body 106 is mounted to a wall of a room, the first and second electrical receptacles 108 and 110 may be exposed to the inside of the room, for example.

In the embodiment shown, the electrical system device body 106 has a stationary wall 124 on the front side 122, and the stationary wall 124 has a channel that defines a first retaining surface 126, a second retaining surface 128 opposite a first portion shown generally at 130 of the first retaining surface 126, and a third retaining surface 132 opposite a second portion shown generally at 134 of the first retaining surface 126. The electrical system device body 106 thus defines a retaining region shown generally at 136 between the first and second retaining surfaces 126 and 128. In the embodiment shown, the retaining region 136 extends to the first side 118 and to the second side 120 of the electrical system device body 106, although alternatively the retaining region 136 may extend to only one of the first and second opposite sides 118 and 120, and may thus be closed off to the other of the first and second opposite sides 118 and 120.

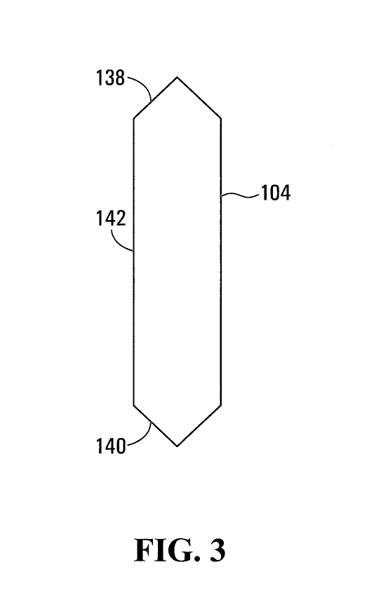

Referring to FIG. 3, the indicia-bearing body 104 in the embodiment shown defines fourth and fifth retaining surfaces 138 and 140, and an indicia-bearing surface 142 between the fourth and fifth retaining surfaces 138 and 140. Herein, “indicia-bearing” may refer to a body, to an element, or to a surface that bears information or other indicia by engraving, embossing, ink, Braille, or illustration, for example, or “indicia-bearing” may refer to a blank body, element, or surface that is configured to bear information or other indicia by engraving, embossing, ink, Braille, or illustration, for example.

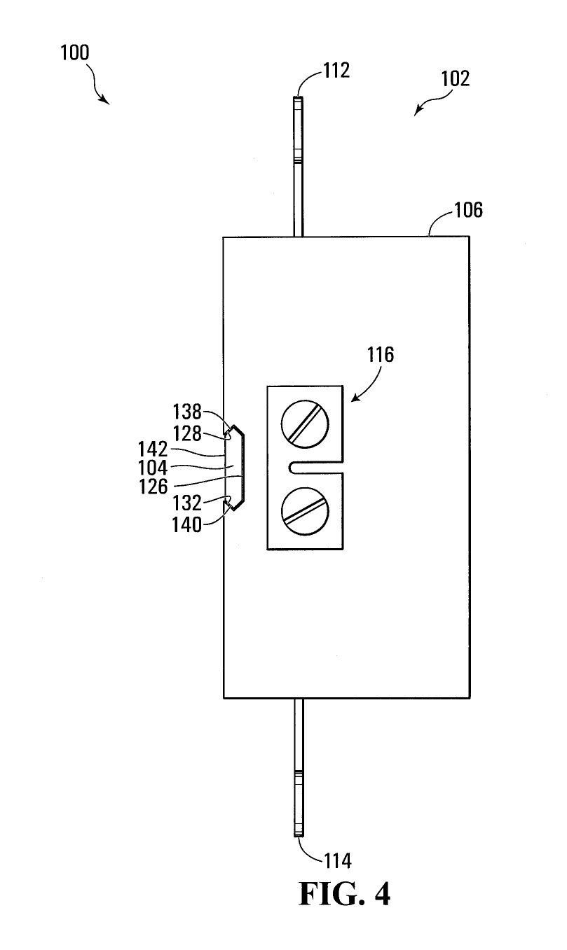

Referring back to FIG. 1, the indicia-bearing body 104 may be received in the retaining region 136 of the electrical system device body 106. Referring to FIG. 4, when the indicia-bearing body 104 is retained in the retaining region 136 (shown in FIGS. 1 and 2), the second and third retaining surfaces 128 and 132 contact the fourth and fifth retaining surfaces 138 and 140 respectively. Thus the second and third retaining surfaces 128 and 132 are complementary to the fourth and fifth retaining surfaces 138 and 140 respectively and prevent the indicia-bearing body 104 from moving forwardly away from the first retaining surface 126 and out of the retaining region (136), thereby retaining the indicia-bearing body 104 in the retaining region (136).

One skilled in the art will appreciate that in the embodiments described herein, surfaces other than those surfaces expressly identified as retaining surfaces may facilitate retaining indicia-bearing bodies in retaining regions. For example, in the embodiment shown in FIG. 4, the fourth and fifth retaining surfaces 138 and 140 are positioned on the indicia-bearing body 104 to retain the indicia-bearing body 104 in the retaining region (136) in a friction fit, and these retaining surfaces co-operate with other surfaces to retain the indicia-bearing body 104 in the friction fit. Advantageously, such a friction fit generally resists movement of the indicia-bearing body 104 towards either of the first and second opposite sides 118 and 120 of the electrical system device body 106, thereby further retaining the indicia-bearing body 104 in the retaining region (136).

Still referring to FIG. 4, the second and third retaining surfaces 128 and 132 are spaced apart in the embodiment shown, and thus expose indicia on the indicia-bearing surface 142 of the indicia-bearing body 104 between the second and third retaining surfaces 128 and 132 when the indicia-bearing body 104 is in the retaining region 136 (shown in FIGS. 1 and 2).

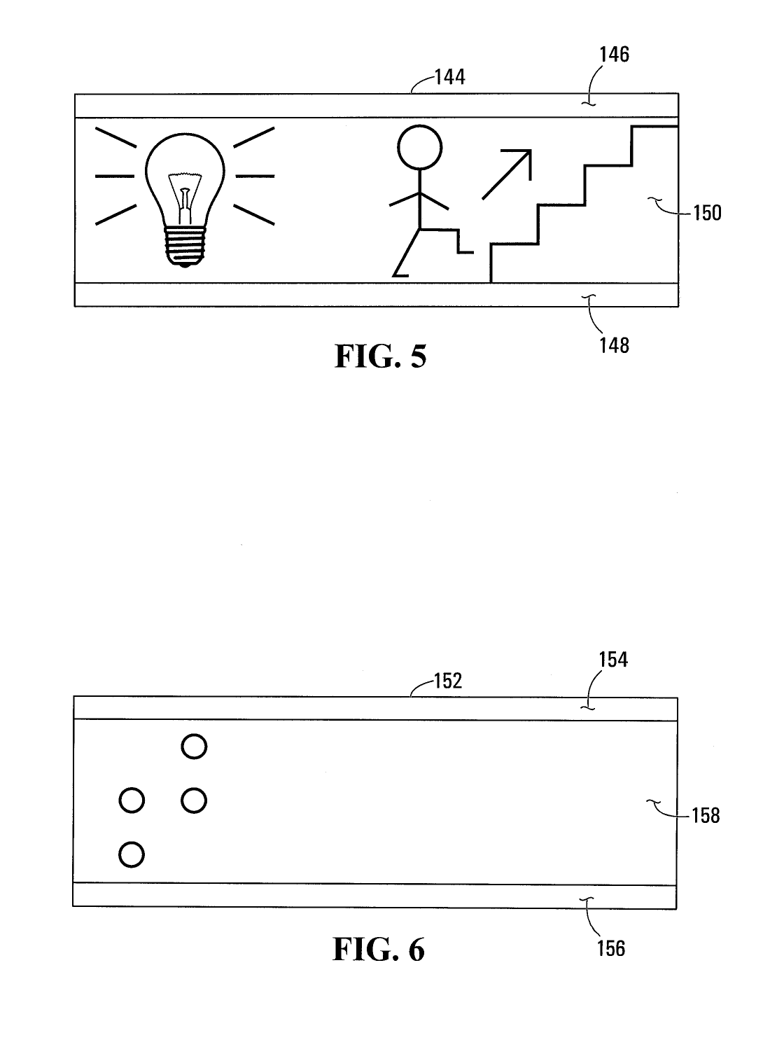

Referring to FIG. 5, another illustrative indicia-bearing body 144 is shown and includes first and second retaining surfaces 146 and 148 and a indicia-bearing surface 150. The first and second retaining surfaces 146 and 148 in the embodiment shown are substantially the same as the second and third retaining surfaces 138 and 140 (shown in FIGS. 1, 3, and 4). However, the indicia-bearing surface 150 includes a pictorial representation.

Referring to FIG. 6, another illustrative indicia-bearing body 152 is shown and includes first and second retaining surfaces 154 and 156 and an indicia-bearing surface 158. The first and second retaining surfaces 154 and 156 in the embodiment shown are substantially the same as the second and third retaining surfaces 138 and 140 (shown in FIGS. 1, 3, and 4). However, the indicia-bearing surface 158 in the embodiment shown includes a Braille character.

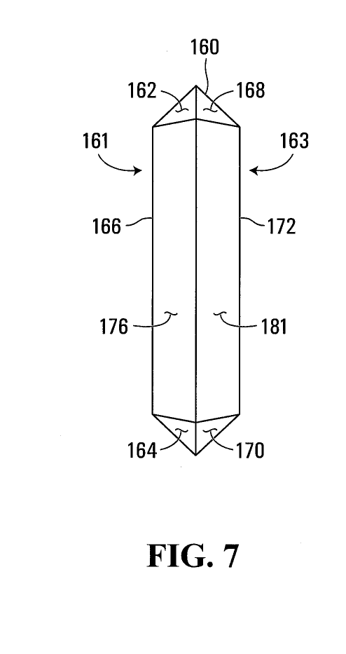

Referring to FIGS. 7, 8, and 9, another illustrative indicia-bearing body 160 is shown and has first and second opposite sides 161 and 163. On the first side 161, the indicia-bearing body 160 includes first and second retaining surfaces 162 and 164 complementary to retaining surfaces such as the second and third retaining surfaces 128 and 132 shown in FIGS. 1, 2, and 4. On the first side 161, the indicia-bearing body 160 also includes a first indicia-bearing surface 166 between the first and second retaining surfaces 162 and 164.

On the second side 163, the indicia-bearing body 160 defines third and fourth retaining surfaces 168 and 170 that are opposite the first and second retaining surfaces 162 and 164 respectively and are also complementary to retaining surfaces such as the second and third retaining surfaces 128 and 132 shown in FIGS. 1, 2, and 4. On the second side 163, indicia-bearing body 160 also defines a second indicia-bearing surface 172 opposite the first indicia-bearing surface 166 and between the third and fourth retaining surfaces 168 and 170.

Therefore, the indicia-bearing body 160 may be received in a retaining region such as the retaining region 136 shown in FIGS. 1 and 2 such that the first side 161 and the first indicia-bearing surface 166 are exposed between the second and third retaining surfaces 128 and 132 shown in FIGS. 1, 2, and 4, or alternatively the indicia-bearing body 160 may be received in the retaining region (136) such that the second side 163 and the second indicia-bearing surface 172 are exposed between the second and third retaining surfaces 128 and 132 shown in FIGS. 1, 2, and 4. The indicia-bearing body 160 is therefore reversible.

Still further, on the first side 161, the indicia-bearing body 160 also defines fifth and sixth retaining surfaces 174 and 176 that extend perpendicularly to the first and second retaining surfaces 162 and 164, and the first, second, fifth, and sixth retaining surfaces 162, 164, 174, and 176 surround the first indicia-bearing surface 166. The fifth and sixth retaining surfaces 174 and 176 are also complementary to retaining surfaces such as the second and third retaining surfaces 128 and 132 shown in FIGS. 1, 2, and 4.

Still further, on the second side 163, the indicia-bearing body 160 also defines seventh and eighth retaining surfaces 179 and 181 that are opposite the fifth and sixth retaining surfaces 174 and 176 respectively and that extend perpendicularly to the third and fourth retaining surfaces 168 and 170, and the third, fourth, seventh, and eighth retaining surfaces 168, 170, 179, and 181 surround the second indicia-bearing surface 172. The seventh and eighth retaining surfaces 179 and 181 are also complementary to retaining surfaces such as the second and third retaining surfaces 128 and 132 shown in FIGS. 1, 2, and 4. The first, second, third, fourth, fifth, sixth, seventh, and eighth retaining surfaces 162, 164, 168, 170, 174, 176, 179, and 181 all have a common length.

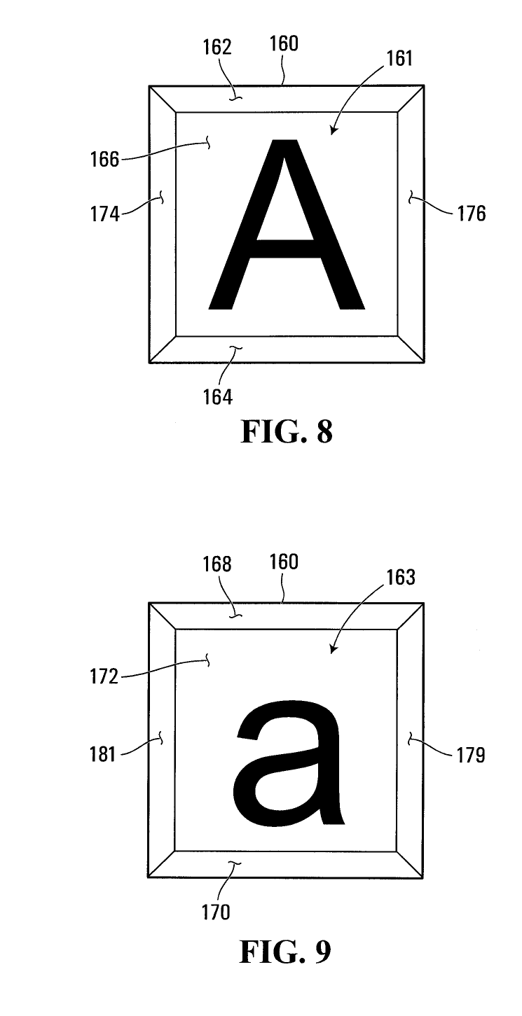

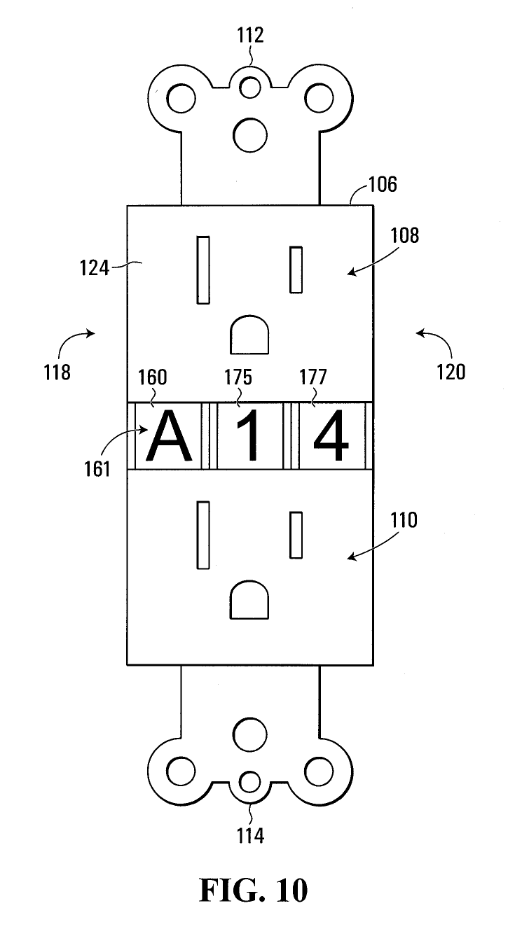

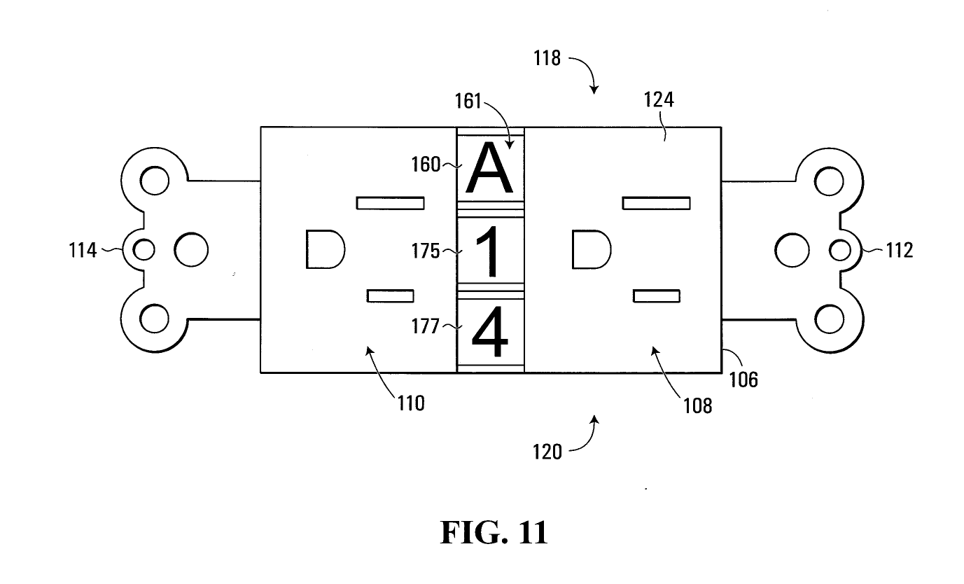

Referring to FIG. 10, the electrical system device body 106 is shown with the indicia-bearing body 160 received in the retaining region 136 (shown in FIGS. 1 and 2) such that the first and second retaining surfaces 162 and 164 (shown in FIGS. 7 and 8) are retained by the second and third retaining surfaces 128 and 132 (shown in FIGS. 1 and 2). Alternatively, referring to FIG. 11, the electrical system device body 106 is shown with the indicia-bearing body 160 retained in the retaining region 136 (shown in FIGS. 1 and 2) with the fifth and sixth retaining surfaces 174 and 176 (shown in FIGS. 7 and 8) retained by the second and third retaining surfaces 128 and 132 (shown in FIGS. 1 and 2). Therefore, the indicia-bearing body 160 is also rotatable. As shown in FIGS. 10 and 11, the retaining region (136) can simultaneously retain the indicia-bearing body 160 and indicia-bearing bodies 175 and 177 that are substantially the same as the indicia-bearing body 160 but bear different indicia.

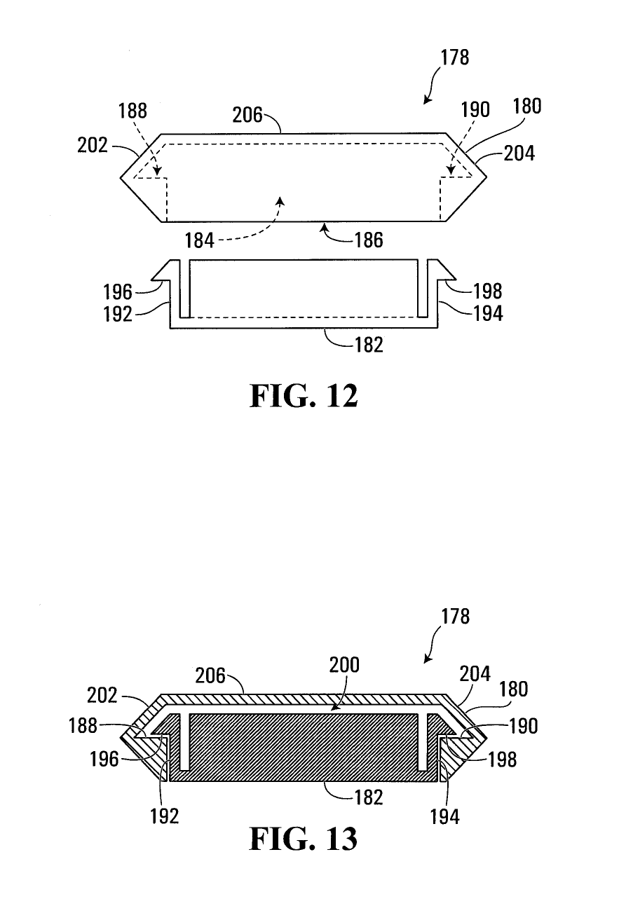

Referring to FIGS. 12 and 13, a further illustrative indicia-bearing body is shown generally at 178, and includes first and second detachably coupleable portions 180 and 182. The first detachably coupleable portion 180 defines a receptacle shown generally at 184 and having an opening shown generally at 186 for receiving the second detachably coupleable portion 182. In the receptacle 184, the first detachably coupleable portion 180 defines first and second ledges 188 and 190 on opposite lateral sides of the receptacle 184 and facing away from the opening 186.

The second detachably coupleable portion 182 includes first and second laterally opposite resiliently moveable members 192 and 194 having respective latching surfaces 196 and 198 positioned to be received on the first and second ledges 188 and 190 respectively when the second detachably coupleable portion 182 is received in the receptacle 184, as shown in FIG. 13. Referring to FIG. 13, when the second detachably coupleable portion 182 is received within the receptacle 184 (shown in FIG. 12) and detachably coupled to the first attachably coupleable portion 180, the first and second detachably coupleable portions 180 and 182 define a repository shown generally at 200 for holding an indicia-bearing element (not shown), which may be a label printed from a label printer, for example.

Referring to FIGS. 12 and 13, the first detachably coupleable portion 180 in the embodiment shown has first and second retaining surfaces 202 and 204 that are complementary to retaining surfaces such as the second and third retaining surfaces 128 and 132 shown in FIGS. 1 and 2, for example. Therefore, the indicia-bearing body 178 may be received within a retaining region such as the retaining region 136 shown in FIGS. 1 and 2, and a front surface 206 of the indicia-bearing body 178 is translucent in the embodiment shown and may be exposed between the second and third retaining surfaces 128 and 132 shown in FIGS. 1 and 2 to expose indicia on an indicia-bearing element (not shown) in the repository 200. Herein, “translucent” refers to a wall or body that allows light to pass, including a wall or body that is transparent in whole or in part.

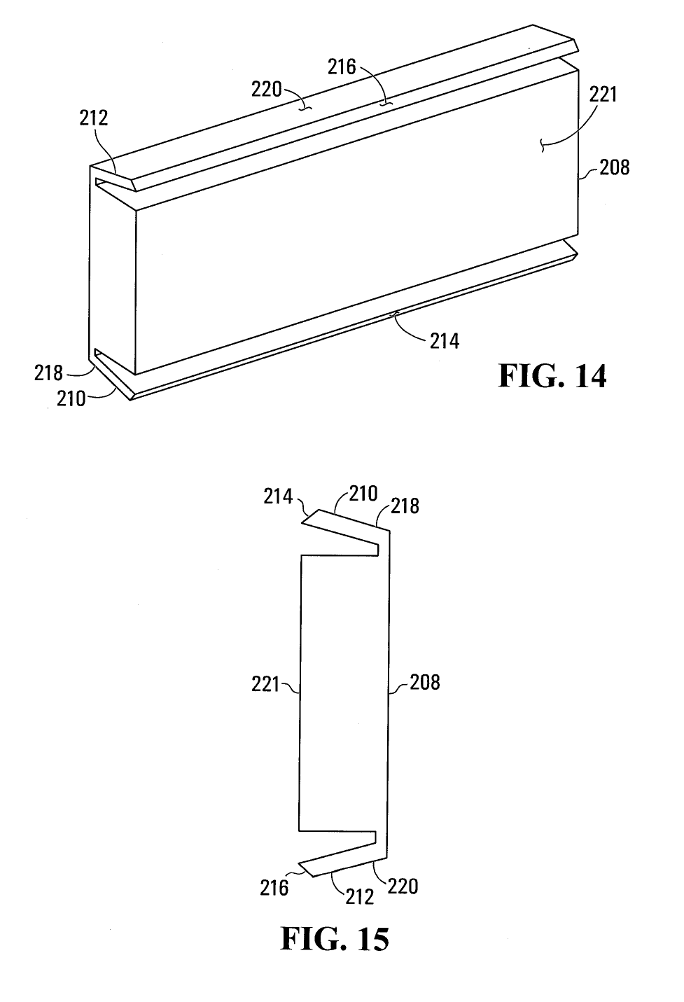

Referring to FIGS. 14 and 15, another illustrative indicia-bearing body 208 is shown and includes first and second laterally opposite resiliently moveable members 210 and 212 having first and second retaining surfaces 214 and 216 respectively and outer surfaces 218 and 220 respectively. The indicia-bearing body 208 also has an indicia-bearing surface 221 between the first and second retaining surfaces 214 and 216 respectively.

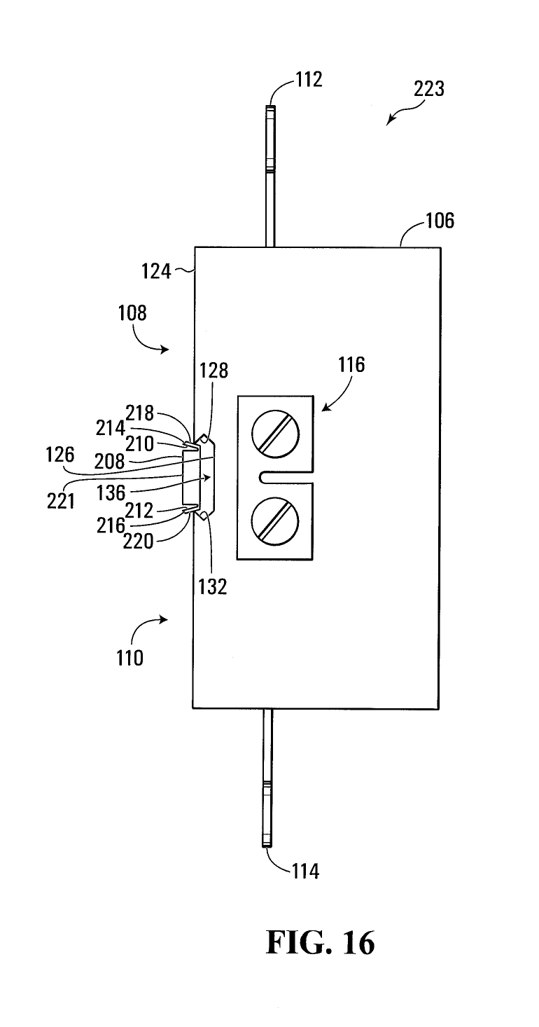

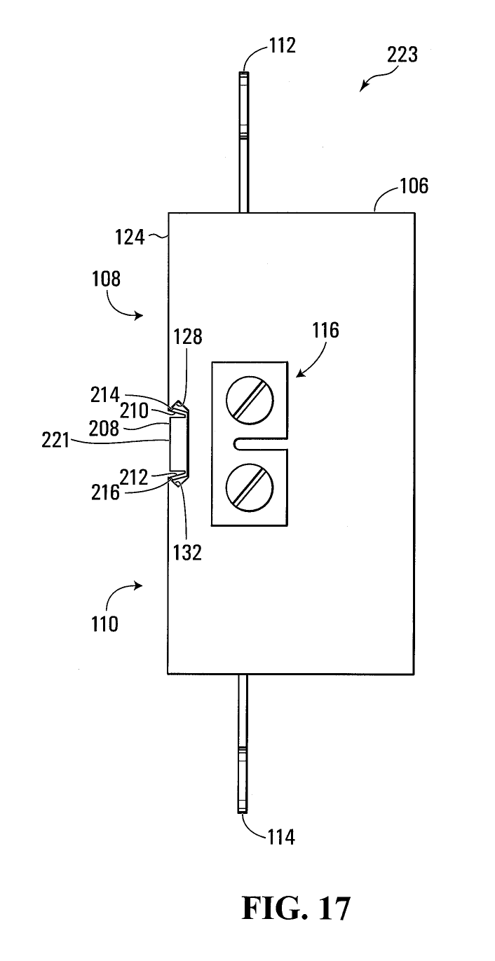

Referring to FIG. 16, another illustrative electrical system device composite is shown generally at 223 and includes the electrical system device body 106 and the indicia-bearing body 208. The outer surfaces 218 and 220 of the indicia-bearing body 208 may be urged against inner portions of the second and third retaining surfaces 128 and 132 when the indicia-bearing body 208 is urged towards the first retaining surface 126 and into the retaining region 136, thereby urging the first and second resiliently moveable members 210 and 212 inwardly towards the indicia-bearing surface 221. Referring to FIG. 17, once the indicia-bearing body 208 is received in the retaining region 136 (shown in FIG. 16), the first and second resiliently moveable members 210 and 212 resiliently move away from the indicia-bearing surface 221, thereby causing the first and second retaining surfaces 214 and 216 of the indicia-bearing body 208 to contact the second and third retaining surfaces 128 and 132 electrical system device body 106 to retain the indicia-bearing body 208 against the first retaining surface 126 and in the retaining region 136 (shown in FIG. 16). In the embodiment shown, the indicia-bearing body 208 may be removed from the retaining region 136 (shown in FIG. 16) by moving the indicia-bearing body 208 towards one of the first and second opposite sides 118 and 120 (shown in FIG. 1).

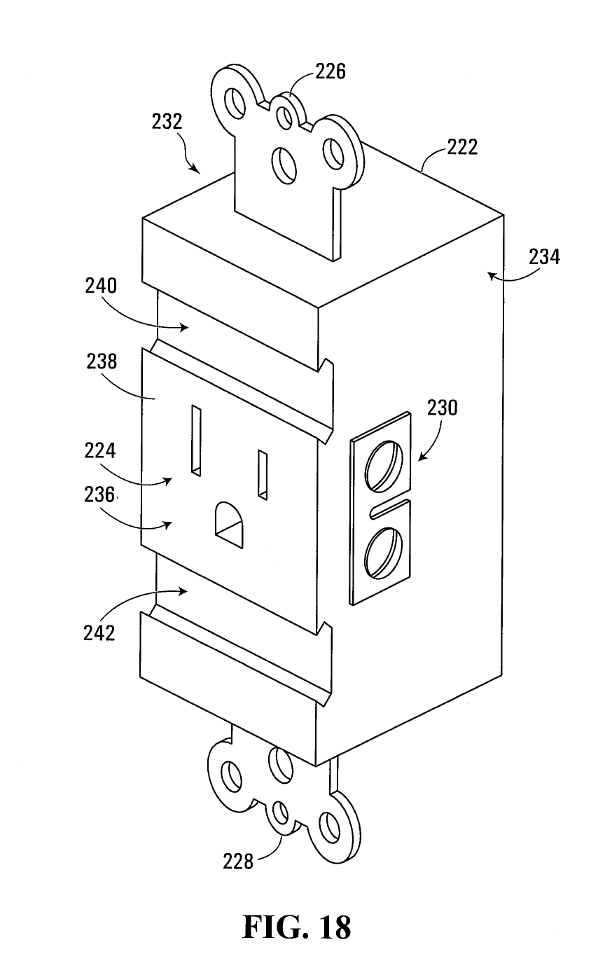

Referring to FIG. 18, another illustrative electrical system device body 222 is shown and has an electrical receptacle shown generally at 224 that is substantially the same as the first or second electrical receptacle 108 or 110 (shown in FIG. 1). The electrical system device body 222 also has first and second mounting members 226 and 228 that are substantially the same as the first and second mounting members 112 and 114 (shown in FIG. 1), and an electrical connector 230 that is substantially the same as the electrical connector 116 (shown in FIG. 1).

The electrical system device body 222 also has first and second opposite sides shown generally at 232 and 234, a front side shown generally at 236, and a stationary wall 238 on the front side 236. The stationary wall 238 defines a first retaining region shown generally at 240 above the electrical receptacle 224, and a second retaining region shown generally at 242 below the electrical receptacle 224. The first and second retaining regions 240 and 242 are substantially the same as the retaining region 136 shown in FIG. 1. Advantageously, the electrical system device body 222 enables receiving one or more indicia-bearing bodies such as those described above, for example, in one or both of the first and second retaining regions 240 and 242.

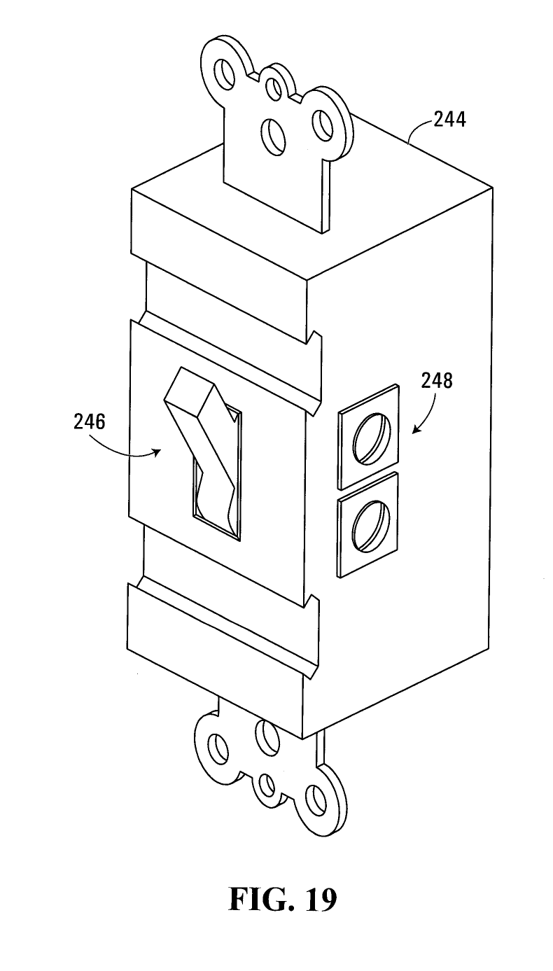

Referring to FIG. 19, another illustrative electrical system device body 244 is shown and is substantially the same as the electrical system device body 222 shown in FIG. 18, except that the electrical system device body 244 has an electrical switch shown generally at 246, and an electrical connector shown generally at 248 and electrically connected to the electrical switch 246 to connect the electrical switch 246 to one or more electrical wires of the electrical system (not shown). More generally, as one skilled in the art will appreciate, the embodiments described herein may include different combinations of one or more electrical devices such as switch actuators, other actuators, and electrical receptacles, for example.

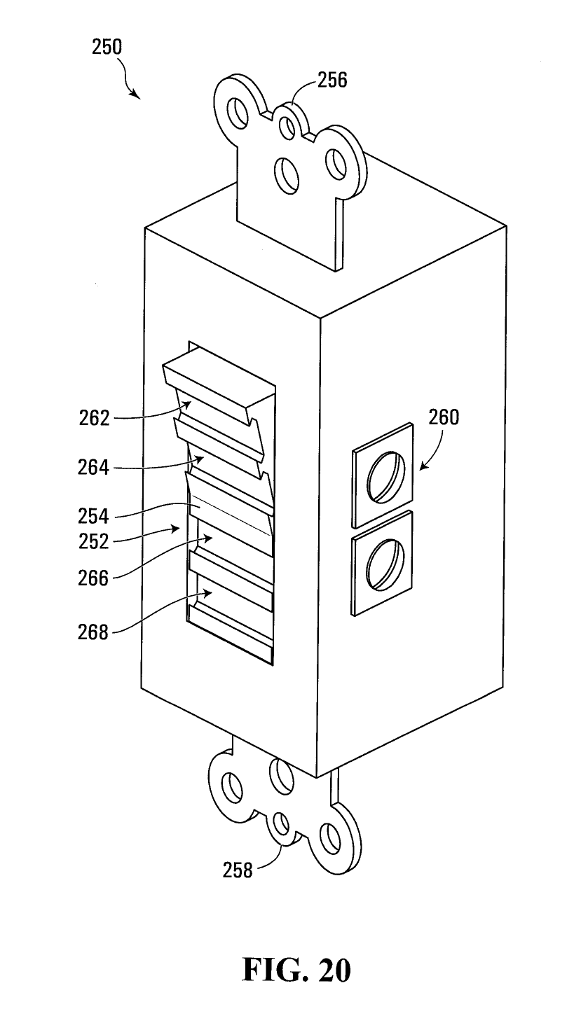

Referring to FIG. 20, another illustrative electrical system device body 250 is shown and includes an electrical switch shown generally at 252 and having a movable portion, which in the embodiment shown is a movable switch actuator 254. The electrical system device body 250 also has first and second mounting members 256 and 258 that are substantially the same as the first and second mounting members 112 and 114 (shown in FIG. 1), and an electrical connector 260 that is substantially the same as the electrical connector 248 shown in FIG. 19.

The movable switch actuator 254 defines first, second, third, and fourth retaining regions shown generally at 262, 264, 266, and 268. The first, second, third, and fourth retaining regions 262, 264, 266, and 268 are substantially the same as the retaining region 136 shown in FIG. 1. Advantageously, the electrical system device body 250 enables receiving one or more indicia-bearing bodies such as those described above, for example, in one or more of the first, second, third, and fourth retaining regions shown generally at 262, 264, 266, and 268. Although the embodiment shown includes a movable switch actuator 254, alternative embodiments may include other movable portions, such as an openable or removable cover, for example.

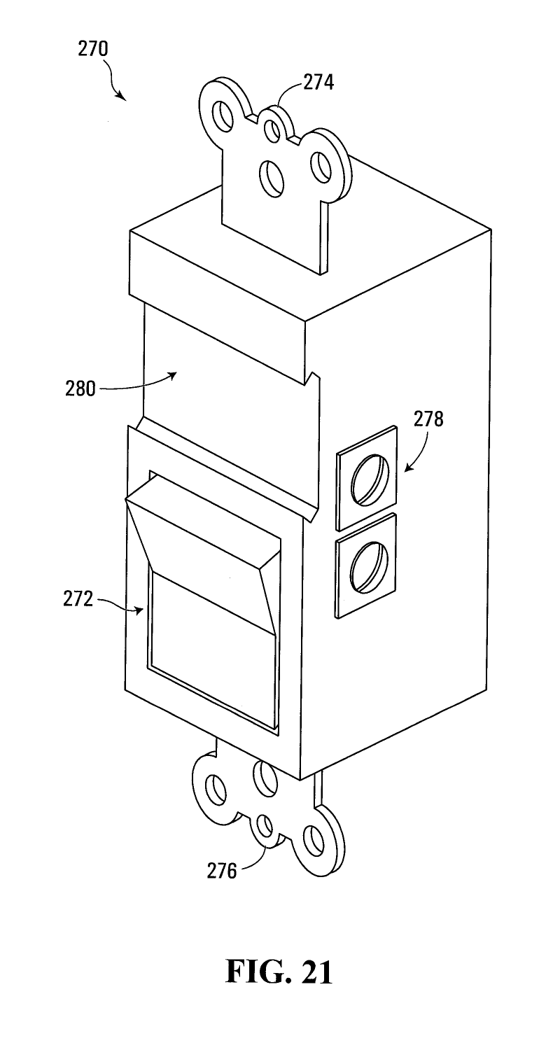

Referring to FIG. 21, another illustrative electrical system device body 270 is shown and has an electrical switch shown generally at 272, first and second mounting members 274 and 276 that are substantially the same as the first and second mounting members 112 and 114 (shown in FIG. 1), and an electrical connector 278 that is substantially the same as the electrical connector 248 shown in FIG. 19. The electrical system device body 270 also has a stationary wall 279 defining a retaining region shown generally at 280. The retaining region 280 is substantially the same as the retaining region 136 shown in FIG. 1, except that the retaining region 280 occupies a greater proportion of a front side of the electrical system device body 270, advantageously enabling the electrical system device body 270 to retain a larger indicia-bearing bodies in the retaining region 280.

Referring back to FIGS. 1 and 2, the first and second retaining surfaces 128 and 132 of the electrical system device body 106 are spaced apart from the first retaining surface 126 by respective joining surfaces 282 and 284, and extend at respective acute angles (that is, less than 90°) 286 and 288 from the first retaining surface 126.

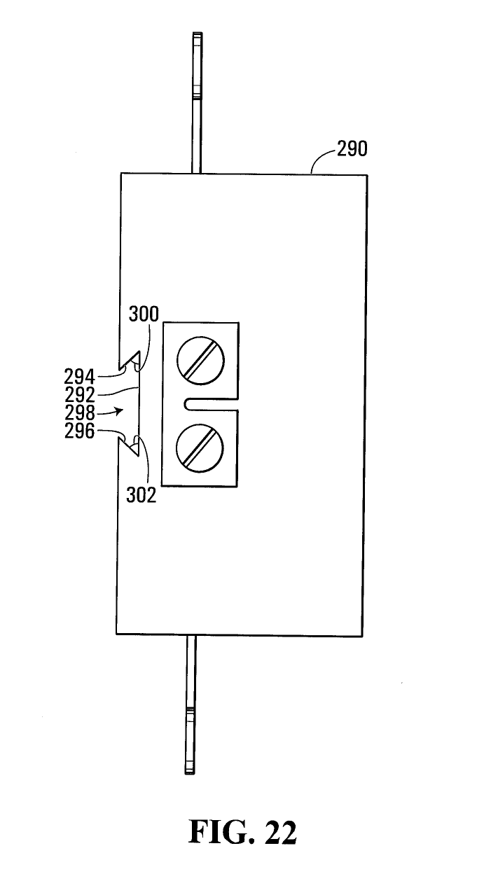

Referring to FIG. 22, another illustrative electrical system device body 290 is shown and defines first, second, and third retaining surfaces 292, 294, and 296 and a retaining region shown generally at 298 between the first and second retaining surfaces 292 and 294. The electrical system device body 290 is substantially the same as the electrical system device body 106 shown in FIG. 1, except that the second and third retaining surfaces 294 and 296 are adjacent the first retaining surface 292 and extend at respective acute angles 300 and 302 from the first retaining surface 292.

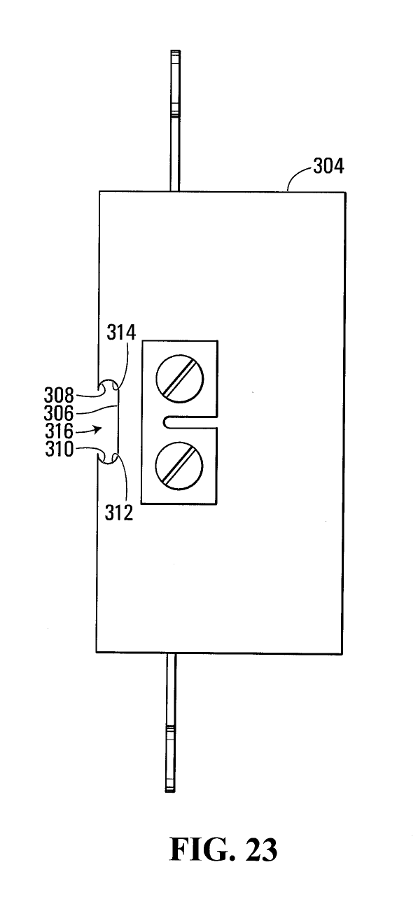

Referring to FIG. 23, another illustrative electrical system device body 304 is shown and defines first, second, and third retaining surfaces 306, 308, and 310, a first joining surface 312 between the first and second retaining surfaces 306 and 308, a second joining surface 314 between the first and third retaining surfaces 306 and 310, and a retaining region shown generally at 316 between the first and second retaining surfaces 306 and 308. The electrical system device body 304 is substantially the same as the electrical system device body 106 shown in FIG. 1, except that the second retaining surface 308 and the first joining surface 312 are continuously curved, and that the third retaining surface 310 and the second joining surface 314 are continuously curved.

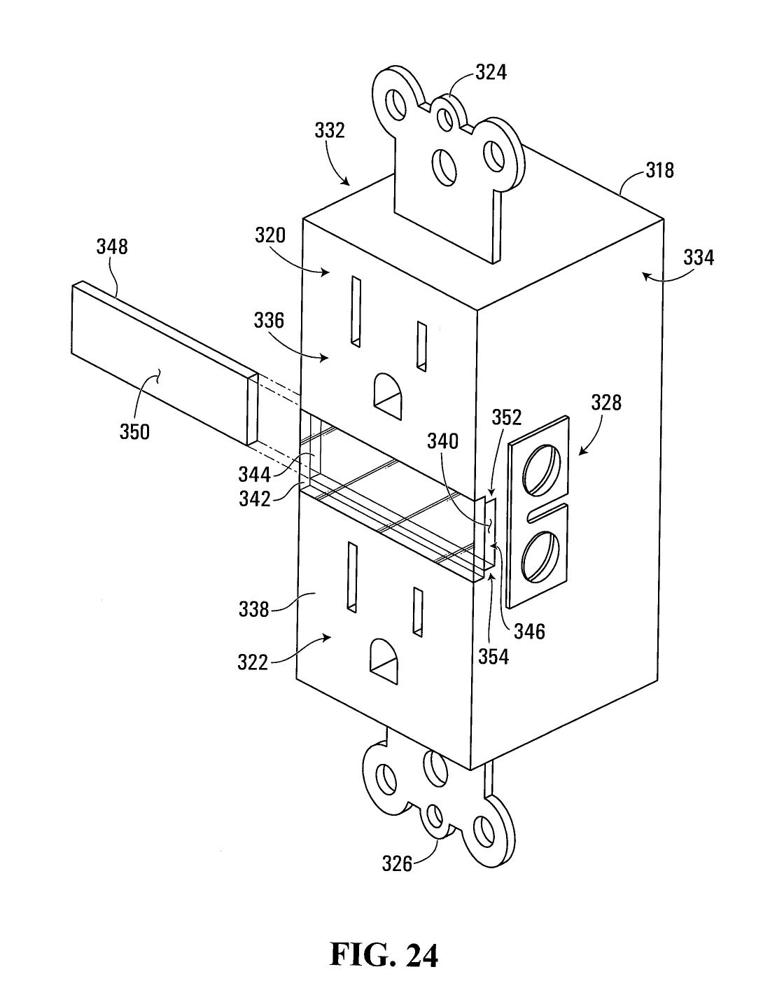

Referring to FIG. 24, another illustrative electrical system device body 318 is shown and has first and second electrical receptacles shown generally at 320 and 322, first and second mounting members 324 and 326, and an electrical connector shown generally at 328, which are substantially the same as the first and second electrical receptacles 108 and 110, the first and second mounting members 112 and 114, and the electrical connector 116 shown in FIG. 1. The electrical system device body 318 also has first and second opposite sides shown generally at 332 and 334, and a front side shown generally at 336. The first and second electrical receptacles 320 and 322 are on the front side 336.

In the embodiment shown, the electrical system device body 318 has a stationary wall 338 on the front side 336, and the stationary wall 338 has a channel that defines a first retaining surface 340. The electrical system device body 318 also has a translucent wall 342 on the front side 336, and the translucent wall 342 has a second retaining surface 344 opposite the first retaining surface 340. The electrical system device body 318 thus defines a retaining region shown generally at 346 between the first and second retaining surfaces 340 and 344. In the embodiment shown, the retaining region 346 extends to the first side 332 and to the second side 334 of the electrical system device body 318, although alternatively the retaining region 346 may extend to only one of the first and second opposite sides 332 and 334, and may thus be closed off to the other of the first and second opposite sides 332 and 334. The retaining region 346 can thus receive an indicia-bearing body 348 having an indicia-bearing surface 350, and indicia on the indicia-bearing surface 350 is visible through the translucent wall 342 when the indicia-bearing body 348 is in the retaining region 346.

In the embodiment shown, the translucent wall 342 is coupled to generally rectangular projections 352 and 354 on top and bottom sides respectively of the retaining region 346, and the generally rectangular projections 352 and 354 are integrally formed with the stationary wall 338.

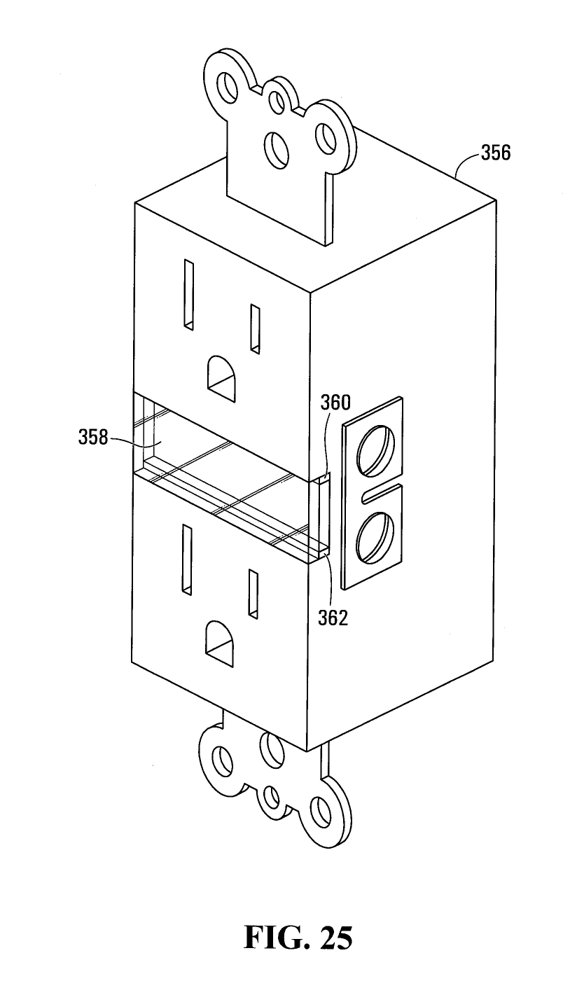

Referring to FIG. 25, another illustrative electrical system device body 356 is shown and is substantially the same as the electrical system device body 318 shown in FIG. 24 except that the electrical system device body 356 includes a translucent wall 358 that is coupled to separately formed generally rectangular members 360 and 362 that function substantially the same as the generally rectangular projections 352 and 354 shown in FIG. 24.

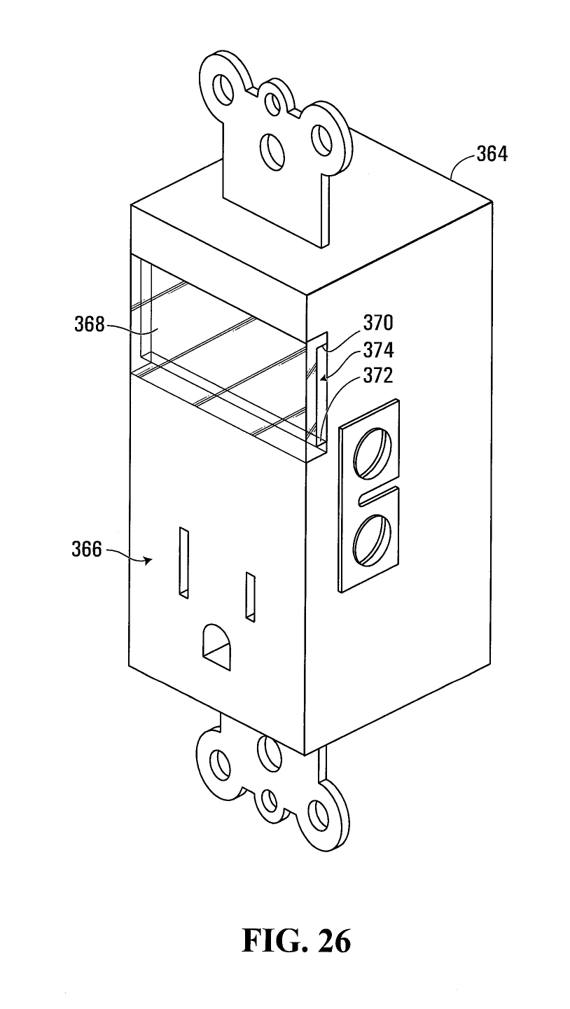

Referring to FIG. 26, another illustrative electrical system device body 364 is shown and is substantially the same as the electrical system device body 318 shown in FIG. 24 except that the electrical system device body 364 includes only one electrical receptacle shown generally at 366, and a translucent wall 368 that includes internal generally rectangular projections 370 and 372 integrally formed with the translucent wall 368 to couple the translucent wall 368 in a channel shown generally at 374 of the electrical system device body 364 without generally rectangular projections 352 and 354 as shown in FIG. 24 or generally rectangular members 360 and 362 as shown in FIG. 25.

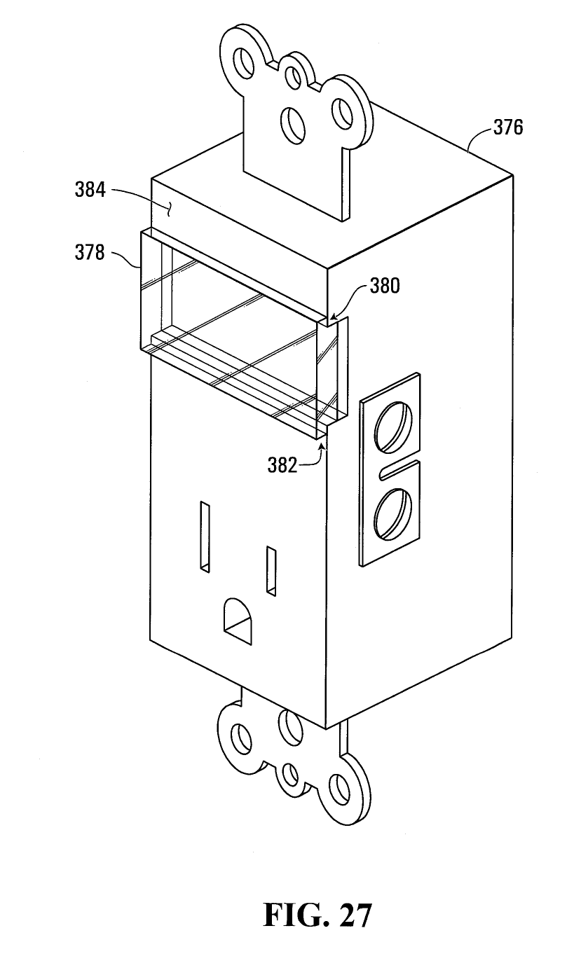

Referring to FIG. 27, another illustrative electrical system device body 376 is shown and is substantially the same as the electrical system device body 364 shown in FIG. 26 except that the electrical system device body 376 includes a translucent wall 378 that includes integrally formed external generally rectangular projections 380 and 382 to couple the translucent wall 378 to an external surface 384 of the electrical system device body 376.

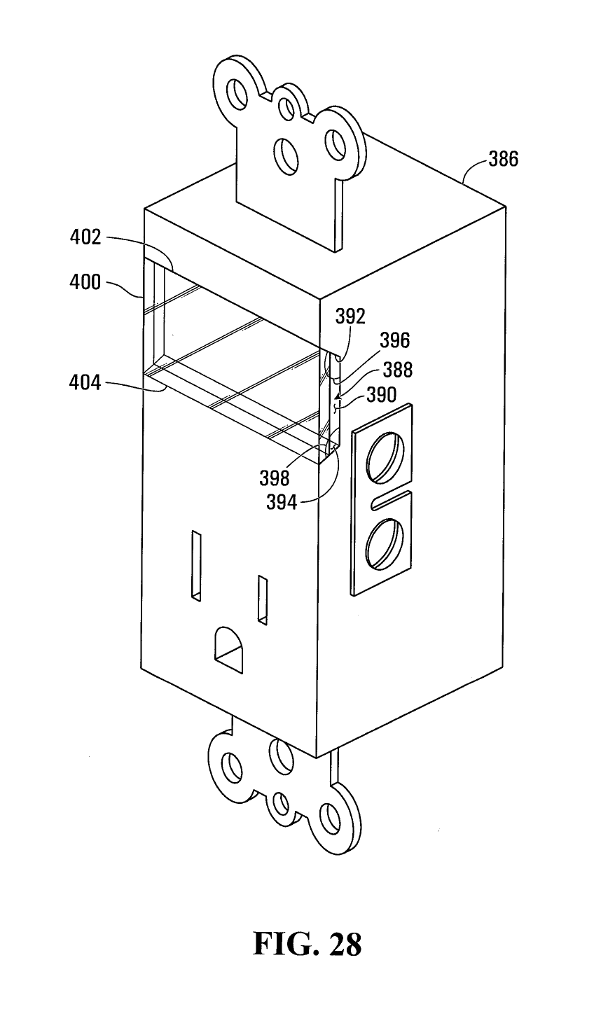

Referring to FIG. 28, another illustrative electrical system device body 386 is shown and is substantially the same as the electrical system device body 364 shown in FIG. 26, although the electrical system device body 386 defines a channel shown generally at 388 and having a first retaining surface 390 and first and second side surfaces 392 and 394 extending at respective oblique angles 396 and 398 from the first retaining surface 390. The electrical system device body 386 also includes a translucent wall 400 that has first and second edges 402 and 404 that are complementary to and coupled to the first and second side surfaces 392 and 394 respectively.

Although FIGS. 24 to 28 illustrate translucent walls on stationary walls to define retaining regions, one skilled in the art will appreciate that such translucent walls may define retaining regions on movable portions such as the movable switch actuator 254 shown in FIG. 20, for example.

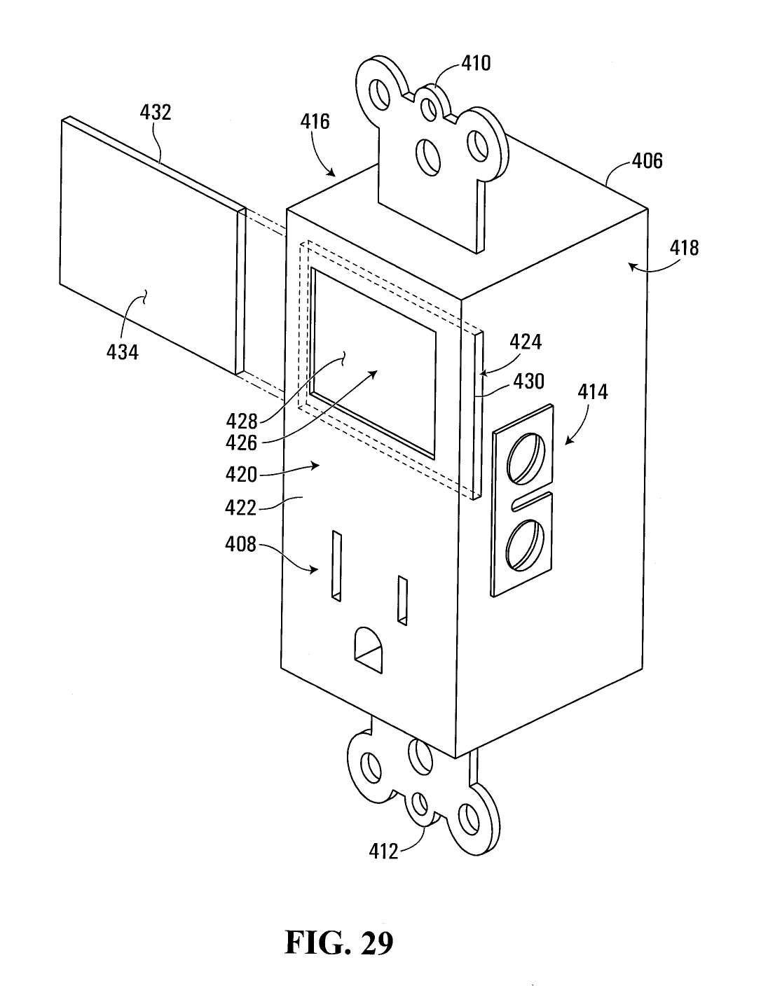

Referring to FIG. 29, another illustrative electrical system device body 406 is shown and has an electrical receptacle shown generally at 408, first and second mounting members 410 and 412, and an electrical connector shown generally at 414, which are substantially the same as the first or second electrical receptacle 108 or 110, the first and second mounting members 112 and 114, and the electrical connector 116 shown in FIG. 1. The electrical system device body 406 also has first and second opposite sides shown generally at 416 and 418, and a front side shown generally at 420. The electrical receptacle 408 is on the front side 420.

In the embodiment shown, the electrical system device body 406 has a stationary wall 422 on the front side 420, and the stationary wall 422 defines a retaining region shown generally at 424 that is open to the front side at an opening shown generally at 426. The retaining region 424 is defined by a first retaining surface 428 opposite the opening 426, and by a second retaining surface 430 opposite the first retaining surface and surrounding the opening 426. In the embodiment shown, the retaining region 424 extends to the first side 416 and to the second side 418 of the electrical system device body 406, although alternatively the retaining region 424 may extend to only one of the first and second opposite sides 416 and 418, and may thus be closed off to the other of the first and second opposite sides 416 and 418. The retaining region 424 can thus receive an indicia-bearing body 432 having an indicia-bearing surface 434, and indicia on the indicia-bearing surface 434 is visible through the opening 426 when the indicia-bearing body 432 is in the retaining region 424.

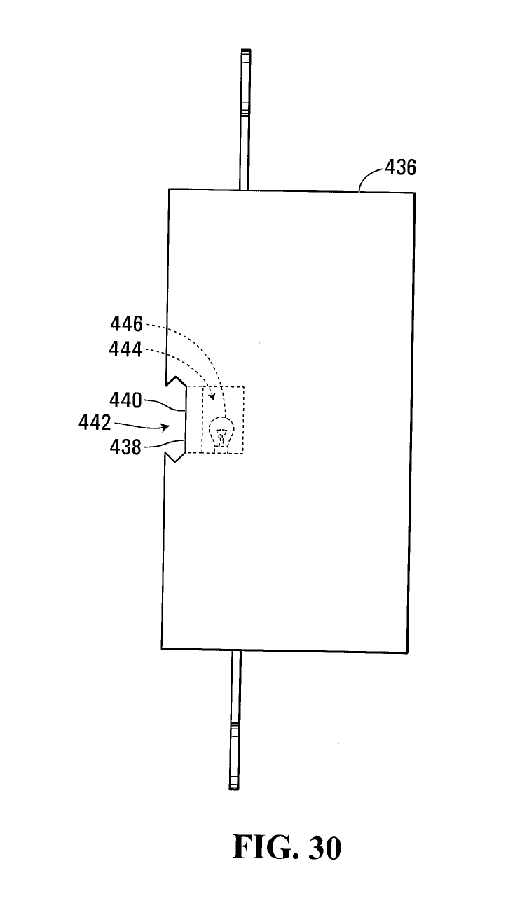

Referring to FIG. 30, another illustrative electrical system device body 436 is shown and is substantially the same as the electrical system device body 106 shown in FIG. 1, except that the electrical system device body 436 includes a translucent wall 438 having a first retaining surface 440 defining a retaining region shown generally at 442, and the electrical system device body 436 also defines an illuminant cavity shown generally at 444 and holding an illuminant 446 proximate the translucent wall 438 to illuminate a translucent indicia-bearing body (not shown) retained in the retaining region 442, advantageously facilitating visibility of indicia on the indicia-bearing body in a dark space. The illuminant 446 may include one or more light-emitting diodes or incandescent light bulbs, for example.

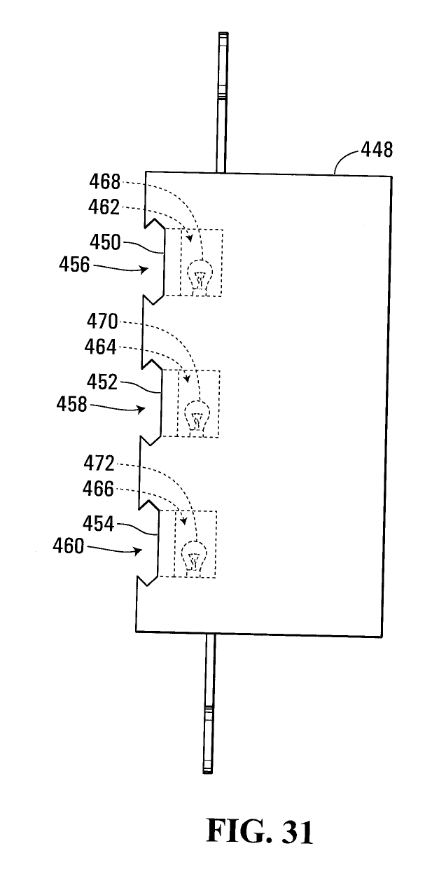

Referring to FIG. 31, another illustrative electrical system device body 448 is shown and is substantially the same as the electrical system device body 436 shown in FIG. 30, although the electrical system device body 448 does not include any electrical receptacles and instead includes first, second, and third translucent walls 450, 452, and 454 that are substantially the same as the translucent wall 438 shown in FIG. 30 and that define first, second, and third retaining regions shown generally at 456, 458, and 460 that are substantially the same as the retaining region 442 shown in FIG. 30. The electrical system device body 448 also includes first, second, and third illuminant cavities that are shown generally at 462, 464, and 466, that are substantially the same as the illuminant cavity 444 shown in FIG. 30, and that hold respective illuminants 468, 470, and 472 to illuminate respective translucent indicia-bearing bodies (not shown) retained in the retaining regions 456, 458, and 460. The electrical system device body 448 may, for example, selectively activate one or more of the illuminants 468, 470, and 472 to convey information.

The retaining regions described above advantageously hold indicia-bearing bodies on electrical system devices themselves, thus advantageously maintaining information or other indicia associated with the electrical system devices even if faceplates of the electrical system devices are removed and replaced on incorrect electrical system devices. Further, the retaining regions described above hold indicia-bearing bodies on electrical system devices without requiring adhesives, and therefore avoid disadvantages of adhesives such as the disadvantages mentioned above, for example. Still further, indicia-bearing bodies may be inserted into or removed from the retaining regions described above without damaging the indicia-bearing bodies, and therefore the retaining regions described above may advantageously permit more reuse of indicia-bearing bodies than if adhesives, for example, were used to hold the indicia-bearing bodies. Further, the retaining regions described above can retain indicia-bearing bodies without requiring a screw fastener system, which may disadvantageously wear with reuse.

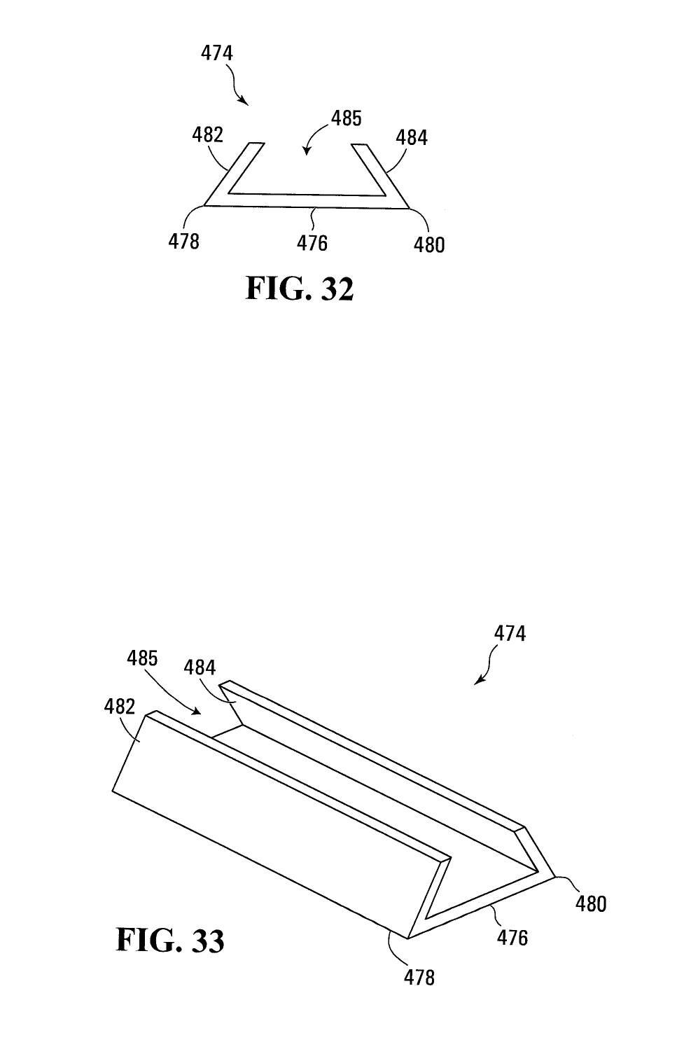

Referring to FIGS. 32 and 33, an illustrative indicia-bearing body holder is shown generally at 474 and includes a generally rectangular base 476 having first and second laterally opposite sides 478 and 480. The indicia-bearing body holder 474 also includes generally rectangular side members 482 and 484 projecting inward and away from the first and second laterally opposite sides 478 and 480 of the base 476. The indicia-bearing body holder 474 thus defines a channel shown generally at 485 between the generally rectangular base 476 and the generally rectangular side members 482 and 484. The channel 485 generally has the shape of the retaining region 298 shown in FIG. 22, and advantageously holds indicia-bearing bodies such as the indicia-bearing body 160 shown in FIGS. 7, 8, and 9 to enable arranging a plurality of such indicia-bearing bodies. After the indicia-bearing bodies are so arranged, the indicia-bearing body holder 474 may be held against one of the aforementioned retaining regions such that the indicia-bearing bodies may be slid into the retaining region. Alternative indicia-bearing body holders may define channels generally corresponding to other retaining regions, such as the retaining regions 136 shown in FIG. 1, 280 shown in FIG. 21, or 316 shown in FIG. 23, for example.

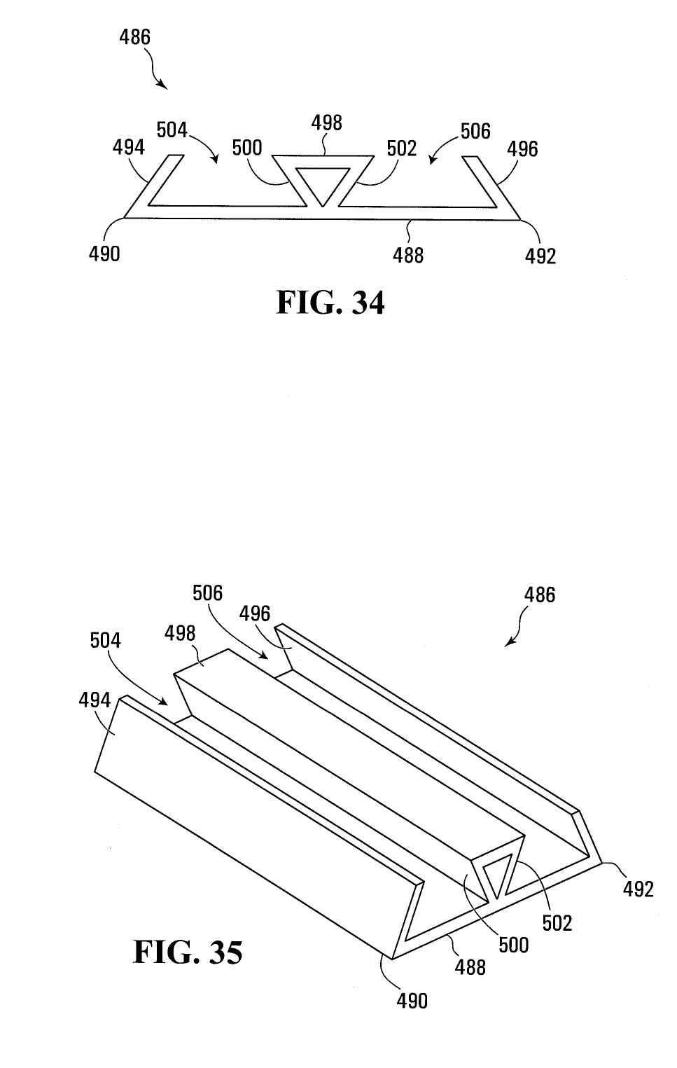

Referring to FIGS. 34 and 35, another illustrative indicia-bearing body holder is shown generally at 486 and includes a generally rectangular base 488 having first and second laterally opposite sides 490 and 492. The indicia-bearing body holder 474 also includes generally rectangular side members 494 and 496 projecting inward and away from the first and second laterally opposite sides 490 and 492 of the base 476. The indicia-bearing body holder 474 also includes a generally triangular member 498 extending parallel to and between the first and second laterally opposite sides 490 and 492 of the base 476 and having opposite surfaces 500 and 502 facing and extending towards the generally rectangular side members 494 and 496. The indicia-bearing body holder 474 thus generally defines channels shown generally at 504 and 506. Each of the channels 504 and 506 has the shape of one of the retaining regions 298 shown in FIG. 22, and advantageously holds indicia-bearing bodies such as the indicia-bearing body 160 shown in FIGS. 7, 8, and 9 to enable arranging a plurality of such indicia-bearing bodies. Again, after the indicia-bearing bodies are so arranged, the indicia-bearing body holder 474 may be held against one of the aforementioned retaining regions such that the indicia-bearing bodies may be slid into the retaining region. And again, alternative indicia-bearing body holders may define two or more channels generally corresponding to other retaining regions, such as the retaining regions 136 shown in FIG. 1, 280 shown in FIG. 21, or 316 shown in FIG. 23, for example.

In other embodiments, the indicia-bearing body holders 474 and 486 may be sized to be received in retaining regions such as the retaining regions 136 shown in FIG. 1, 280 shown in FIG. 21, 298 shown in FIG. 22, or 316 shown in FIG. 23, for example. In such embodiments, the indicia-bearing body holders 474 and 486 may be referred to as indicia-bearing bodies, and the channels 485, 504, and 506 may be referred to as repositories for holding one or more indicia-bearing elements.

While specific embodiments have been described and illustrated, such embodiments should be considered illustrative only and not as limiting the invention as construed in accordance with the accompanying claims.

1. An electrical system device having an electrical connector for connecting the electrical system device to one or more electrical wires of an electrical system, the electrical system device comprising:
a mountable electrical system device body having first and second opposite sides and a front side between the first and second opposite sides, the electrical system device body having at least one electrical device on the front side and defining:
a first retaining surface on the front side;
a second retaining surface on the front side and opposite at least a first portion of the first retaining surface; and
a retaining region between the first and second retaining surfaces for retaining an indicia-bearing body, the retaining region extending to at least one of the first and second opposite sides to receive the indicia-bearing body from the at least one of the first and second opposite sides.

2. The electrical system device of claim 1 wherein the at least one electrical device on the front side includes a switch actuator.

3. The electrical system device of claim 1 wherein the at least one electrical device on the front side includes an electrical receptacle.

4. The electrical system device of claim 1 wherein the electrical system device body comprises a first translucent wall having the first retaining surface, and wherein the electrical system device body further comprises an illuminant for illuminating the indicia-bearing body through the first translucent wall when the indicia-bearing body is in the retaining region.

5. The electrical system device of claim 4 wherein the electrical system device body further comprises a second translucent wall having the second retaining surface to permit visible indicia on the indicia-bearing body to be visible on the front side of the electrical system device body when the indicia-bearing body is in the retaining region.

6. The electrical system device of claim 5 wherein the electrical system device body includes a stationary wall on the front side, the stationary wall having the first retaining surface and holding the second translucent wall.

7. The electrical system device of claim 5 wherein the electrical system device body includes a movable portion on the front side, the movable portion having the first retaining surface and holding the second translucent wall.

8. The electrical system device of claim 1 wherein the electrical system device body further defines a third retaining surface on the front side and opposite a second portion of the first retaining surface for retaining the indicia-bearing body in the retaining region, the third retaining surface spaced apart from the second retaining surface to expose indicia on the indicia-bearing body between the second and third retaining surfaces when the indicia-bearing body is in the retaining region.

9. The electrical system device of claim 8 wherein the second and third retaining surfaces extend at respective acute angles from the first retaining surface.

10. The electrical system device of claim 9 wherein the second and third retaining surfaces are spaced apart from the first retaining surface.

11. The electrical system device of claim 9 wherein the second and third retaining surfaces are adjacent the first retaining surface.

12. The electrical system device of claim 8 wherein the second retaining surface and a surface joining the first and second retaining surfaces are continuously curved, and wherein the third retaining surface and a surface joining the first and third retaining surfaces are continuously curved.

13. The electrical system device of claim 8 wherein the electrical system device body includes a stationary wall on the front side, the stationary wall having the first, second, and third retaining surfaces.

14. The electrical system device of claim 8 wherein the electrical system device body includes a movable portion on the front side, the movable portion having the first, second, and third retaining surfaces.

15. An electrical system device kit comprising:
an indicia-bearing body; and
a mountable electrical system device body having first and second opposite sides and a front side between the first and second opposite sides, the electrical system device body having at least one electrical device on the front side and defining:
a first retaining surface on the front side;
a second retaining surface on the front side and opposite at least a first portion of the first retaining surface; and
a retaining region between the first and second retaining surfaces for retaining an indicia-bearing body, the retaining region extending to at least one of the first and second opposite sides to receive the indicia-bearing body from the at least one of the first and second opposite sides;
wherein the electrical system device body further defines a third retaining surface on the front side and opposite a second portion of the first retaining surface for retaining the indicia-bearing body in the retaining region, the third retaining surface spaced apart from the second retaining surface to expose indicia on the indicia-bearing body between the second and third retaining surfaces when the indicia-bearing body is in the retaining region,
wherein the indicia-bearing body defines fourth and fifth retaining surfaces complementary to the second and third retaining surfaces respectively to retain the indicia-bearing body in the retaining region of the electrical system device body.

16. The kit of claim 15 wherein the fourth and fifth retaining surfaces are positioned to cause the first, second, and third retaining surfaces to retain the indicia-bearing body in the retaining region in a friction fit.

17. The kit of claim 15 wherein the indicia-bearing body further has a first indicia-bearing surface between the fourth and fifth retaining surfaces.

18. The kit of claim 17 wherein the indicia-bearing body further has:
sixth and seventh retaining surfaces opposite the fourth and fifth retaining surfaces respectively and complementary to the second and third retaining surfaces respectively to retain the indicia-bearing body in the retaining region of the electrical system device body; and
a second indicia-bearing surface between the sixth and seventh retaining surfaces and opposite the first indicia-bearing surface.

19. The kit of claim 18 wherein the indicia-bearing body further defines eighth and ninth retaining surfaces complementary to the second and third retaining surfaces respectively, wherein the eighth and ninth retaining surfaces extend perpendicularly to the third and fourth retaining surfaces, and wherein the fourth, fifth, eighth, and ninth retaining surfaces have a common length and surround the first indicia-bearing surface.

20. The kit of claim 15 wherein the indicia-bearing body defines a repository for holding at least one indicia-bearing element.

21. The kit of claim 20 wherein the indicia-bearing body comprises first and second detachably couplable portions defining the repository for holding the indicia-bearing element between the first and second detachably couplable portions when the first and second detachably couplable portions are coupled.

22. The kit of claim 21 wherein the first detachably couplable portion has the fourth and fifth retaining surfaces and defines a receptacle for receiving the second detachably couplable portion.

23. The kit of claim 15 wherein the indicia-bearing body includes first and second latches having the fourth and fifth retaining surfaces respectively, the first and second latches being resiliently movable to permit the indicia-bearing body to move between the second and third retaining surfaces when the indicia-bearing body is urged into the retaining region towards the first retaining surface.

24. The kit of claim 15 wherein at least a portion of the indicia-bearing body is translucent.

25. The kit of claim 15 further comprising an indicia-bearing body holder for holding a plurality of said indicia-bearing bodies.
